(19) United States
(12) Patent Application Publication
(10) Pub. No.: US 2007/0232048 A1
(43) Pub. Date: Oct. 4, 2007

(54) Damascene interconnection having a SiCOH low k layer

(76) Inventors: Koji Miyata, Mahopac, NY (US); Sujatha Sankaran, Wappingers Falls, NY (US); Theodorus Eduardus Fransiscus Maria Standaert, Pine Bush, NY (US); Ricardo Alves Donaton, Cortlandt Manor, NY (US)

Correspondence Address: MAYER & WILLIAMS PC, 251 NORTH AVE. WEST, 2ND FLOOR, WESTFIELD, NJ, 07090, US

(21) Appl. No.: 11/395,962

(22) Filed: Mar. 31, 2006

(51) Int. Cl. H01L 21/44

(52) U.S. Cl. 438/597

(57) ABSTRACT

A method and apparatus is provided for fabricating a damascene interconnection. The method begins by forming on a substrate an organosilicate dielectric layer, a capping layer on the organosilicate dielectric layer, and a resist pattern over the capping layer to define a first interconnect opening. The capping layer is etched through the resist pattern using a first etchant. The resist pattern is removed after etching the capping layer. The dielectric layer is etched through the capping layer using a second etchant different from the first etchant to form the first interconnect opening. An interconnection is completed by filling the first interconnect opening with conductive material.

### FIELD OF THE INVENTION

The present invention relates generally to single and dual damascene interconnections for integrated circuits, and more specifically to a single or dual damascene interconnection having a SiCOH low k layer and a cap layer that are etched in separate etching steps.

### BACKGROUND OF THE INVENTION

The manufacture of integrated circuits in a semiconductor device involves the formation of a sequence of layers that contain metal wiring. Metal interconnects and vias which form horizontal and vertical connections in the device are separated by insulating layers or inter-level dielectric layers (ILDs) to prevent crosstalk between the metal wiring that can degrade device performance. A popular method of forming an interconnect structure is a dual damascene process in which vias and trenches are filled with metal in the same step to create multi-level, high density metal interconnections needed for advanced high performance integrated circuits. The most frequently used approach is a via first process in which a via is formed in a dielectric layer and then a trench is formed above the via. Recent achievements in dual damascene processing include lowering the resistivity of the metal interconnect by switching from aluminum to copper, decreasing the size of the vias and trenches with improved lithographic materials and processes to improve speed and performance, and reducing the dielectric constant (k) of insulators or ILDs by using so-called low k materials to avoid capacitance coupling between the metal interconnects. The expression “low-k” material has evolved to characterize materials with a dielectric constant less than about 3.9. One class of low-k material that have been explored are organic low-k materials, typically having a dielectric constant of about 2.0 to about 3.8, which may offer promise for use as an ILD.

Many of the low k materials, however, have properties that are incompatible with other materials employed to fabricate semiconductor devices or are incompatible with processes employed to fabricate the semiconductor devices. For example, adhesion to layers formed from a low dielectric constant material by adjacent layers is often poor, resulting in delamination. Additionally, layers formed from low dielectric materials are often structurally compromised by Chemical Mechanical Polishing (CMP) processes through erosion, as well as adsorption of CMP slurry chemicals. Etching processes often produce micro-trenches and rough surfaces in layers formed from materials having low dielectric constants, which is often unsuitable for subsequent photolithography processes. As a result, these materials are problematic to integrate into damascene fabrication processes. To overcome some of these problems a cap or capping layer typically formed from a material such as SiO₂ is employed to protect the low dielectric materials during the CMP processes. The cap layer also serves as a hardmask when the vias and trenches are etched.

FIGS. 1-3 show the formation of a conventional single damascene structure that is used to form vias 150₁ and 150₂. The single damascene structure shown in FIG. 3 includes a substrate 100 and a SiO₂ lower interconnection 105 in which various active and passive devices such as gate 112 may be formed. The SiO₂ lower interconnection 110 also includes a via 110 below via 150₁. A SiCOH low-k ILD layer 130 is formed over the SiO₂ lower interconnection 105 and a capping layer 145 is formed over SiCOH layer 130.

Referring to FIG. 1, vias 150 are formed by application of a photoresist pattern 145 over the capping layer 140. In FIG. 2 the capping layer 140 and SiCOH layer 130 are anisotropically etched by a conventional Reactive Ion Beam Etch (RIE) using etch gases such as CF₄ or CHF₃. Unfortunately, these etch gases are not highly selective to the SiCOH layer 130 and the SiO₂ lower interconnection 105. Moreover, the etch rate of the SiCOH layer is low compared to the etch rate of the SiO₂ layer 105. As a result, the etch process will etch both the SiCOH layer 130 and the SiO₂ layer 105. Accordingly, to ensure that contact is established between via 150₁ and via 110, the via 150₁ is over-etched, as indicated generally by reference numeral 116.

One problem that arises from over-etching via 150₁ is illustrated in FIG. 4, which shows three vias 160₁, 160₂ and 160₃ having increasing widths. The vias 160 are similar to the vias 150 shown in FIGS. 2 and 3. As shown, because the vias 160 are over-etched, their depths necessarily increase as their widths increase. This is undesirable for a number of reasons. For instance, if gates 112₁, and 112₂ are located below vias 160₂ and 160₃, respectively, the distance between the bottom of the respective via 160 and the top of the gate 112 will depend on the via width.

Returning to the formation of a conventional single damascene structure shown in FIGS. 1-3, after the vias 150 are formed, the photoresist pattern 145 is removed using a conventional stripper. The stripper unfortunately may damage the sidewalls of the vias 150 that are formed of SiCOH.

Accordingly, it would be desirable to provide a method for forming a single or dual damascene structure in which interconnect openings such as via and trenches may be formed in SiCOH low k materials without the need to over-etch and without causing damage to the interconnect opening sidewalls.

### SUMMARY OF THE INVENTION

In accordance with the present invention, a method and apparatus is provided for fabricating a damascene interconnection. The method begins by forming on a substrate an organosilicate dielectric layer, a capping layer on the organosilicate dielectric layer, and a resist pattern over the capping layer to define a first interconnect opening. The capping layer is etched through the resist pattern using a first etchant. The resist pattern is removed after etching the capping layer. The dielectric layer is etched through the capping layer using a second etchant different from the first etchant to form the first interconnect opening. An interconnection is completed by filling the first interconnect opening with conductive material.

In accordance with one aspect of the invention, the damascene interconnection is a dual damascene interconnection and a second resist pattern is applied over the capping layer and the dielectric layer is etched to form a second interconnect opening that is connected to the first interconnect opening and in which interconnections will be formed.

In accordance with another aspect of the invention, the organosilicate dielectric layer is formed from SiCOH.

In accordance with another aspect of the invention, a second dielectric layer is formed on the substrate over which the organosilicate dielectric layer is formed.

In accordance with another aspect of the invention, the second dielectric layer is SiO₂.

In accordance with another aspect of the invention, at least one active or passive device is formed in the SiO₂ layer.

In accordance with another aspect of the invention, a lower interconnection is formed in the SiO₂ layer.

In accordance with another aspect of the invention, the step of etching the capping layer is performed by a RIE process using at least one main etch gas.

In accordance with another aspect of the invention, the main etch gas is selected from the group consisting of CₓF_{y} and CₓH_{y}F_{z}.

In accordance with another aspect of the invention, the step of etching the dielectric layer is performed by a RIE process using at least a second main etch gas.

In accordance with another aspect of the invention, the second main etch gas is selected from the group consisting of F₂, SF₆ and NF₃.

In accordance with another aspect of the invention, the first interconnect opening is a via.

In accordance with another aspect of the invention, the first interconnect opening is a trench.

In accordance with another aspect of the invention, the capping layer comprises SiNₓC_{y}H_{z}.

In accordance with another aspect of the invention, an embedded etch stop layer is formed in the organosilicate dielectric layer.

In accordance with another aspect of the invention, an integrated circuit is provided having a damascene interconnection constructed in accordance with any of the aforementioned methods.

### BRIEF DESCRIPTION OF THE DRAWINGS

FIGS. 1-3 show cross-sectional views illustrating the formation of a conventional single damascene structure.

FIG. 4 shows a cross-sectional view illustrating a problem that arises from over-etching vias of increasing widths using a conventional damascene process.

FIGS. 5-8 show cross-sectional views illustrating the formation of a single damascene structure constructed in accordance with the present invention.

FIG. 9 shows a cross-sectional view similar to that depicted in FIG. 4 except using a damascene process in accordance with the present invention.

FIGS. 10-16 show the formation of a damascene structure constructed in accordance with an alternative embodiment of the present invention.

### DETAILED DESCRIPTION

The methods and structures described herein do not form a complete process for manufacturing semiconductor device structures. The remainder of the process is known to those of ordinary skill in the art and, therefore, only the process steps and structures necessary to understand the present invention are described herein.

The present invention can be applied to microelectronic devices, such as highly integrated circuit semiconductor devices, processors, micro electromechanical (MEM) devices, optoelectronic devices, and display devices. In particular, the present invention is highly useful for devices requiring high-speed characteristics, such as central processing units (CPUs), digital signal processors (DSPs), combinations of a CPU and a DSP, application specific integrated circuits (ASICs), logic devices, and SRAMs.

Herein, an opening exposing a lower interconnection is referred to as a via, and a region where interconnections will be formed is referred to as a trench. Hereinafter, the present invention will be described by way of an example of a via-first dual damascene process. However the present invention is also applicable to other dual damascene processes as well.

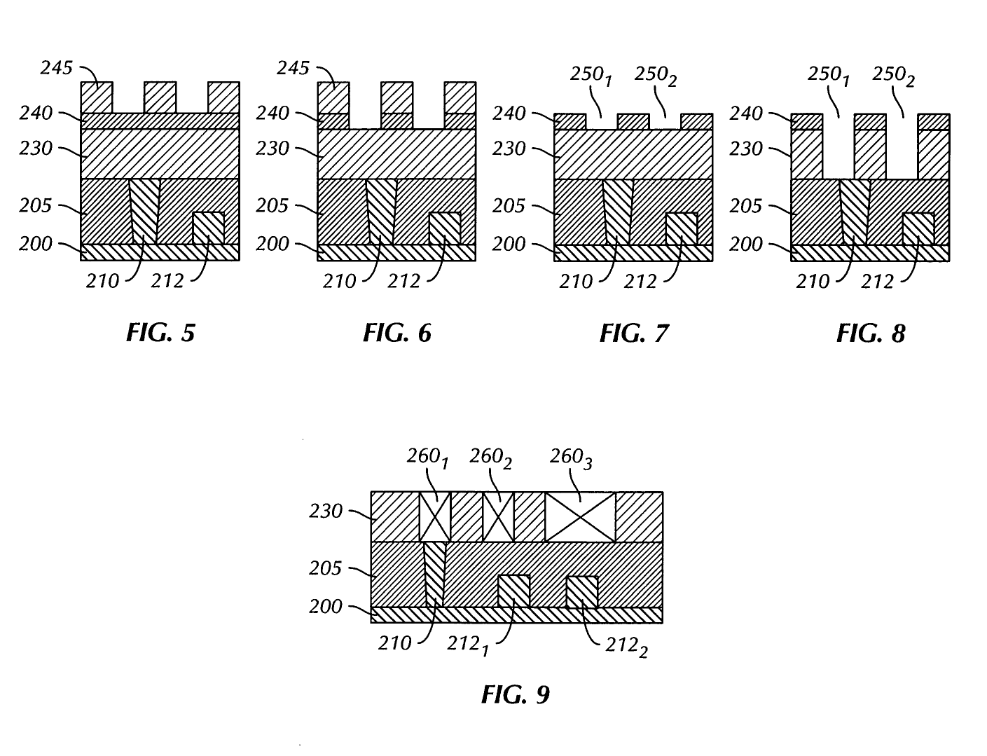

In the present invention the aforementioned problems that can arise when a via or trench is etched in an SiCOH low-k dielectric layer are overcome by etching the capping layer and the SiCOH layer in different process steps using different etch gases. Moreover, the photoresist used to define the via or trench is removed after the capping layer is etched but before the SiCOH layer is etched, thereby avoiding damage to the via or trench sidewalls during the resist stripping process. A method of fabricating single or dual damascene interconnections according to an embodiment of the present invention will now be described with reference to FIG. 5 through 8, which shows the fabrication of single damascene interconnection. Those of ordinary skill in the art will recognize that the invention is equally applicable to dual damascene interconnection structures.

As shown in FIG. 5, a substrate 200 is prepared. A lower ILD layer 205 including a lower interconnection 210 is formed on the substrate 200. The substrate 200 may be, for example, a silicon substrate, a silicon on insulator (SOI) substrate, a gallium arsenic substrate, a silicon germanium substrate, a ceramic substrate, a quartz substrate, or a glass substrate for display. In the present example, lower ILD layer 205 is formed from SiO₂. Various active devices and passive devices may be formed in the ILD layer 205. For instance, a gate 212 formed from silicon is shown in FIG. 5. The lower interconnection 210 may be formed of various interconnection materials, such as copper, copper alloy, aluminum, aluminum alloy, and tungsten. Also, the surface of the lower interconnection 210 is preferably planarized.

Referring to FIG. 5, a low-k ILD layer 230 and a capping layer 240 are sequentially stacked on the surface of the substrate 200 where the lower interconnection 210 is formed, and a photoresist pattern 245 is formed on the capping layer 240 to define one or more vias.

The ILD layer 230 is formed of a hybrid low-k dielectric material, which has advantages of organic and inorganic materials. In particular, ILD layer 230 is formed from an organosilicate glass (OSG), also known as SiCO, which is oxygen doped silicon carbide. When SiCO has a significant hydrogen content, it is also referred to as SiCOH which is available as Black Diamond™ from Applied Materials, CORAL™ from Novellus, or can be obtained by different trade names from other manufacturers. While the precise composition of SICOH can vary, Black Diamond, for example, has been analyzed by RBS (Rutherford Back Scattering) and shown to have a composition of about 20 atomic weight % silicon, about 30 at. wt. % oxygen, about 9 at. wt. % carbon, and about 36 at. wt. % hydrogen. SiCOH has a k value between about 2 and 3 and thereby provides a much needed reduction in capacitance coupling between wiring. The composition and properties of SiCOH may vary depending on deposition conditions and source gases. Typically, a silane and an oxidizing gas are flowed into a heated process chamber where a chemical vapor deposition (CVD) or a plasma enhanced CVD (PECVD) process occurs. Optionally, a single precursor may function as the silicon, carbon/hydrogen, and oxygen source gas and is usually assisted into the process chamber with an inert carrier gas. The ILD layer 230 is formed to a thickness of about 3,000 angstroms to 20,000 angstroms or other appropriate thicknesses determined by those skilled in the art.

In general, the deposition process parameters used to form the ILD layer 230 using a PECVD process chamber may be readily determined by those of ordinary skill in the art. Such process parameters include wafer temperature, chamber pressure, precursor gas flow rate, oxygen enhancement gas flow rate, inert carrier gas flow rate, and RF power level. Helium (He), argon (Ar), nitrogen (N₂), or combinations thereof, among others, may be used to form the plasma.

Referring again to FIG. 5, capping layer 240 is formed over ILD layer 230. The capping layer 240 prevents the ILD layer 230 from being damaged when dual damascene interconnections are planarized using chemical mechanical polishing (CMP). The capping layer 240 also serves as a hardmask during the subsequent etching steps used to form the via and trench. Suitable materials for the capping layer 240 are tailored by the particular dielectric materials used in constructing the structure and can be determined by those skilled in the art without undue experimentation once aware of this disclosure. For example, for SiCOH based structures, the capping layer materials may include a nitride material such as SiN, SICN or NBLOK™, which has the composition SiNₓC_{y}H_{z}.

After formation of ILD layer 230 and capping layer 240, the process continues by forming the via photoresist pattern 245 by depositing a layer of photoresist and then performing exposure and developing processes using a photo mask defining a via. Referring to FIG. 6, the capping layer 240 is anisotropically etched (147) using the photoresist pattern 245 as an etch mask to form portions of vias 250₁ and 250₂. The capping layer 240 can be etched in a conventional manner using, for example, a reactive ion beam etch (RIE) process, which uses a mixture of a main etch gas (e.g., CₓF_{y} and CₓH_{y}F_{z}), an inert gas (e.g. Ar gas), and possibly at least one of O₂, N₂, and COₓ. Here, the RIE conditions are adjusted such that only the capping layer 240 is selectively etched and the ILD layer 230 is not etched.

Referring to FIG. 7, the via photoresist pattern 245 is removed using a stripper. If the photoresist pattern 245 is removed using O₂-ashing, which is widely used for removing a photoresist pattern, the ILD layer 230, which often contains carbon, may be damaged by the O₂-based plasma. Thus, the photoresist pattern 245 alternatively may removed using an H₂-based plasma.

Referring to FIG. 8 after removal of the photoresist pattern 245, the SICOH ILD layer 230 is etched to complete formation of vias 250₁ and 250₂ using, for example, a reactive ion beam etch (RIE) process, which uses a mixture of a main etch gas (e.g., F₂ SF₆ and NF₃), an inert gas (e.g. Ar gas), and possibly at least one of O₂, and N₂. Importantly, the etch gases that are employed to etch the ILD layer 230 do not contain carbon and thus provides better selectivity with respect to SiO₂ and a higher etch rate with respect to SICOH.

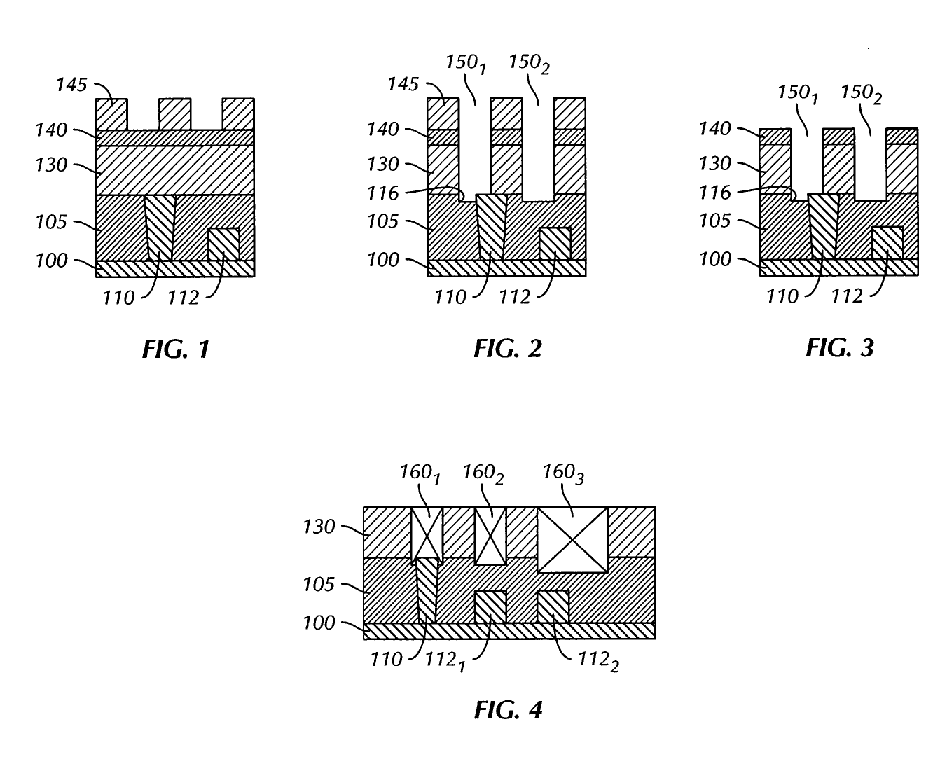

In contrast to a conventional process such as shown in FIGS. 1-3, in which the capping layer 240 and the ILD 230 are etched by RIE in the same processing step using the same etch gases, the present invention etches the capping layer 240 in a first RIE etch step (shown in FIG. 6) that employs one set of etch gases and etches the ILD 230 in a second RIE etch step (shown in FIG. 8) that employs a second set of etch gases. In this way the resist 240 is removed before etching the SIOH, thus preventing damage to the via sidewalls in the SiOH ILD 230 that could otherwise arise from the stripper. Moreover, the SiOH ILD 230 advantageously can be etched with more appropriate etch gases that offer a higher selectivity to SiO₂. The higher selectively avoids the need to over-etch the vias 150, as performed in the conventional process depicted in FIGS. 1-3.

FIG. 9 shows three vias 260₁, 260₂ and 260₃ having increasing widths, which is similar to FIG. 4, discussed above. The vias 260 are formed in a SiCOH material in accordance with the present invention as depicted in FIGS. 5-8. As shown, because the vias 260 are not over-etched, their depths do not increase as their widths increase. Accordingly, the distance between the bottom of the respective via 260 and the top of the gate 212 will not depend on the via width.

As previously mentioned, a dual damascene interconnect structure may be formed as well as a single damascene interconnect structure. In a dual damascene interconnect structure, after formation of one or more vias as in FIG. 8, a trench photoresist pattern is formed over the capping layer 240. Once again, in accordance with the present invention, the capping layer 240 and the SiCOH layer 230 are etched in separate process steps to form a trench in layer 230. The trench photoresist is also removed between etching the capping layer and the SICOH layer 230. Of course, those of ordinary skill in the art will recognize that in addition to a via-first dual damascene process such as described above the present invention can be applied to a trench-first dual damascene process.

In addition to the aforementioned advantages provided by the present invention, other advantages include a reduced etching time, a thinner capping layer, simplified resist removal process, and a simplified process to fill the vias with metal since the via top that is formed will be naturally rounded.

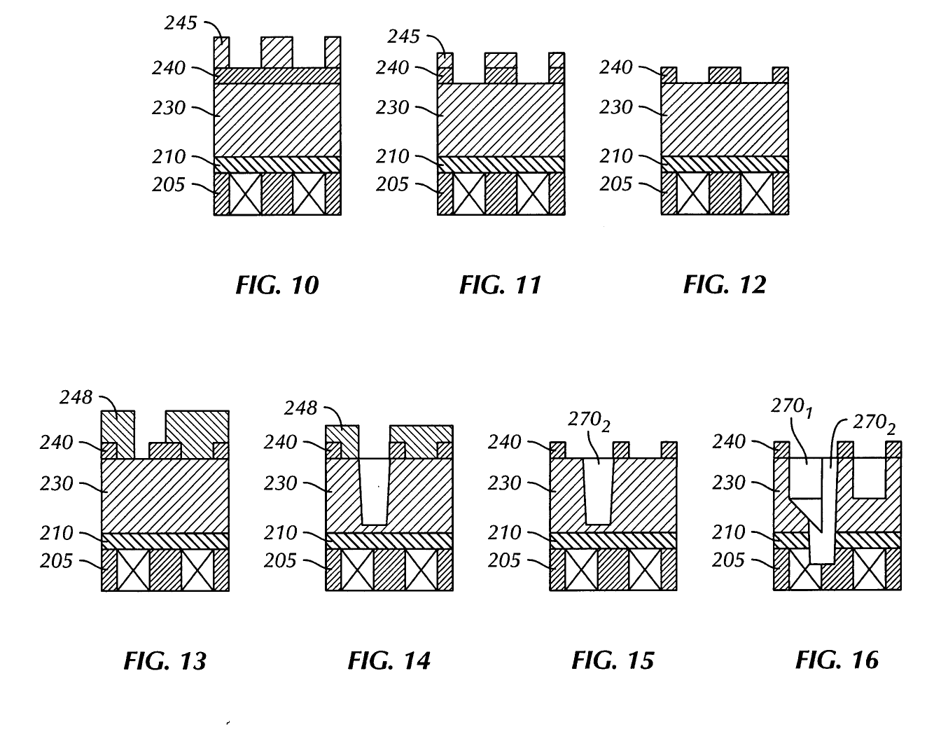

FIGS. 10-16 show a process for forming a damascene structure that includes a trench 270₁ and a via 270₂. In FIGS. 5-8 and 10-16 like elements are denoted by like reference numerals. The process is largely similar to the process discussed above. However, in contrast to the embodiment of the invention depicted in FIGS. 5-8, a cap layer 210 serving as an etch stop is employed in FIGS. 10-16, which is located between SiO₂ dielectric layer 205 and SiCOH dielectric layer 230. In addition, a second resist 248 is employed to define via 2702.

Although various embodiments are specifically illustrated and described herein, it will be appreciated that modifications and variations of the present invention are covered by the above teachings and are within the purview of the appended claims without departing from the spirit and intended scope of the invention. For example, an embedded barrier or etch stop layer may be formed in the SiCOH dielectric layer to prevent over-eching of the vias and to better control via depth. Accordingly, the etch stop layer is formed of a material having a high etch selectivity with respect to the ILD layer formed thereon. For instance, in the case of an SiCOH dielectric layer, the etch stop layer may be formed from SiO₂. The etch stop layer is preferably as thin as possible in consideration of the dielectric constant of the entire ILD layer, but thick enough to properly function as an etch stop layer. Other variations include, in a dual damascene process, the provision of an oxide hardmask on the lower metallization level to even better prevent over-etching of an upper level via. In this case the via is selectively etched to the top of the hardmask. It should be noted that such a hardmask will be retained during the CMP process that is employed on the lower metallization level. In yet another embodiment of the invention, the SiN or SiC capping layer that is situated between the lower metallization layer and the subsequently formed low-k dielectric layer is selectively applied only over the interconnects may be applied to the lower metallization, thereby reducing the overall interconnect capacitance.

1. A method of fabricating a damascene interconnection, comprising:
(a) forming on a substrate an organosilicate dielectric layer;
(b) forming a capping layer on the organosilicate dielectric layer;
(c) forming a resist pattern over the capping layer to define a first interconnect opening;
(d) etching the capping layer through the resist pattern using a first etchant;
(e) removing the resist pattern after etching the capping layer;
(f) etching the dielectric layer through the capping layer using a second etchant different from the first etchant to form the first interconnect opening; and
(g) completing an interconnection by filling the first interconnect opening with conductive material.

2. The method of claim 1 wherein the damascene interconnection is a dual damascene interconnection and further comprising the steps of applying a second resist pattern over the capping layer and etching the dielectric layer to form a second interconnect opening that is connected to said first interconnect opening and in which interconnections will be formed.

3. The method of claim 1 wherein the organosilicate dielectric layer is formed from SICOH.

4. The method of claim 3 further comprising the step of forming a second dielectric layer on the substrate over which the organosilicate dielectric layer is formed.

5. The method of claim 4 wherein the second dielectric layer is SiO₂.

6. The method of claim 5 further comprising at least one active or passive device formed in the SiO₂ layer.

7. The method of claim 5 further comprising a lower interconnection formed in the SiO₂ layer.

8. The method of claim 1 wherein the step of etching the capping layer is performed by a RIE process using at least one main etch gas.

9. The method of claim 8 wherein the main etch gas is selected from the group consisting of CₓF_{y} and CₓH_{y}F_{z}.

10. The method of claim 8 wherein the step of etching the dielectric layer is performed by a RIE process using at least a second main etch gas.

11. The method of claim 10 wherein the second main etch gas is selected from the group consisting of F₂, SF₆ and NF₃.

12. The method of claim 1 wherein the first interconnect opening is a via.

13. The method of claim 1 wherein the first interconnect opening is a trench.

14. The method of claim 3 wherein said capping layer comprises SiNₓC_{y}H_{z}.

15. The method of claim 2 further comprising forming an embedded etch stop layer in the organosilicate dielectric layer.

16. An integrated circuit having a damascene interconnection constructed in accordance with the method of claim 1.

17. A method of fabricating a damascene interconnection, comprising:
(a) forming on a substrate an SiO₂ dielectric layer;
(b) forming over the SiO₂ layer an SiCOH dielectric layer;
(c) forming a capping layer on the SiCOH dielectric layer; d) forming a resist pattern over the capping layer to define a first interconnect opening;
(e) etching the capping layer through the resist pattern using a first etchant;
(f) removing the resist pattern after etching the capping layer;
(g) etching the SiCOH dielectric layer through the capping layer using a second etchant that contains fluorine to form the first interconnect opening; and
(h) completing an interconnection by filling the first interconnect opening with conductive material.

18. The method of claim 17 wherein the second etchant is selected from the group consisting of F₂, SF₆ and NF₃.

19. A method of etching an SiCOH layer, comprising:
(a) forming on a substrate an SiO₂ dielectric layer;
(b) forming over the SiO₂ layer an SiCOH dielectric layer;
(c) forming a capping layer on the SiCOH dielectric layer;
(d) forming a resist pattern over the capping layer to define a feature to be etched in the SoCOH layer;
(e) etching the capping layer through the resist pattern using a first etchant;
(f) removing the resist pattern after etching the capping layer; and
(g) etching the SiCOH dielectric layer through the capping layer using a second etchant that contains fluorine to form the feature.

20. The method of claim 19 wherein the second etchant is selected from the group consisting of F₂, SF₆ and NF₃.
